(19) United States
(12) Patent Application Publication
(10) Pub. No.: US 2011/0018646 A1
(43) Pub. Date: Jan. 27, 2011

(54) LC VOLTAGE-CONTROLLED OSCILLATOR

(75) Inventors: Hui Dong LEE, Daejeon (KR); Seok Ju Yun, Daejeon (KR); Kwi Dong Kim, Daejeon (KR); Jong Kee Kwon, Daejeon (KR)

Correspondence Address: AMPACC Law Group, PLLC, 6100 219th Street SW, Suite 580, Mountlake Terrace, WA, 98043, US

(73) Assignee: Electronics and Telecommunications Research Institute, Daejeon (KR)

(21) Appl. No.: 12/840,478

(22) Filed: Jul. 21, 2010

(30) Foreign Application Priority Data
Jul. 27, 2009 (KR) 10-2009-0068378
Mar. 8, 2010 (KR) 10-2010-0020194

(51) Int. Cl. H03B 5/12

(52) U.S. Cl. 331/117 FE

(57) ABSTRACT

An LC voltage-controlled oscillator (VCO) is provided. According to the LC voltage-controlled oscillator (VCO), the amplitude of an oscillation signal is improved by increasing the impedance value of an amplifier circuit seen from an output node in an LC voltage-controlled oscillator (VCO), and phase noise is also improved.

### CROSS-REFERENCE TO RELATED APPLICATION

This application claims priority to and the benefit of Korean Patent Application No. 10-2009-0068378, filed Jul. 27, 2009 and Korean Patent Application No. 10-2010-0020194, filed Mar. 8, 2010, the disclosure of which is incorporated herein by reference in its entirety.

### BACKGROUND

1. Field of the Invention

The present invention relates to an LC voltage-controlled oscillator (VCO), and more particularly to an LC VCO that includes an amplifier circuit having a high impedance value and thus can output an oscillation signal having a large amplitude and exhibit improved phase noise performance.

2. Discussion of Related Art

A VCO is a circuit whose oscillation signal can vary in frequency according to voltage applied from the outside, and is used as an important component in a wireless transceiver.

Among VCOs, an LC-type VCO uses negative resistance (−gₘ) according to a positive feedback of a circuit. The oscillation signal of such an oscillator can be controlled by controlling a capacitance value of the circuit using a control signal.

As an LC-type VCO, a negative conductance LC oscillator using a negative resistance characteristic according to a positive feedback of a transistor is widely known.

FIG. 1 is a circuit diagram of a general LC VCO.

As shown in FIG. 1, a general LC VCO includes an LC resonant circuit 110 including one or two inductors L₁, a capacitor C₅ connected in parallel with the inductor L₁, and variable capacitors C₃ and C₄ of two varactor diodes, and an amplifier circuit 120 having a positive feedback circuit including two transistors M₁ and M₂ whose gates and drains are connected and a transistor M₃ functioning as a current source.

Also, both ends of the inductor L₁ and the variable capacitors C₃ and C₄ connected in series are connected to output nodes outp and outn, and drains of the transistors M₁ and M₂ included in the amplifier circuit 120 are connected to the output nodes outp and outn respectively.

The LC VCO oscillates when an absolute value |R_{T}| of an impedance R_{T}=−2/g_{μ} of a positive feedback circuit constituting the amplifier circuit 120 is an equivalent resistance of the LC resonant circuit 110 or less. The oscillation frequency varies according to the inductance value of the inductor L₁ included in the LC resonant circuit 110 or the capacitance values of the capacitors C₃ and C₄.

In general, a spiral inductor consisting of a spiral line and an outgoing line is used as the inductor L₁ and formed on the same substrate as the transistors M₁ and M₂. Here, the inductance value of the inductor L₁ varies discretely, and it is very difficult to control the oscillation frequency by adjusting the inductance value. Thus, a fixed value is used as the inductance value of the inductor L₁, and a method of adjusting the capacitance values of the variable capacitors C₃ and C₄ by applying a control signal vc to the variable capacitors C₃ and C₄ constituting the varactor diodes is widely used to control the oscillation frequency. Here, the variable range of the capacitance values of the varactor diodes corresponds to the variable range of the oscillation frequency.

Meanwhile, a phase noise index, which is a typical performance value of an overall LC VCO, is defined as a difference between the power value of the oscillation frequency and a power value at a position spaced apart from the oscillation frequency by a specific offset frequency.

Thus, to improve the phase noise performance, the signal level of the oscillation frequency must be increased, or the power value at the specific offset frequency must be reduced. The signal level of the oscillation frequency is determined as the reciprocal of a combined conductance obtained by combining the negative conductance of the amplifier circuit 120 and the conductance of the resonant circuit 110, i.e., a combined impedance. Thus, the greater the impedance value of the amplifier circuit 120 seen from the output nodes outp and outn, the higher the signal level of the oscillation frequency. Meanwhile, one factor increasing the power value at the specific offset frequency is flicker noise of a current source, that is, 1/f noise. The flicker noise approaches the oscillation frequency due to an up-conversion mechanism, and thus the phase noise deteriorates.

Consequently, it is necessary to immediately develop technology for increasing the signal level of an oscillation frequency by increasing the impedance value of an amplifier circuit, and improving the phase noise performance of an overall LC VCO by improving the 1/f noise of a current source.

### SUMMARY OF THE INVENTION

The present invention is directed to improving the amplitude of an oscillation signal by increasing the impedance value of an amplifier circuit seen from an output node in an LC voltage-controlled oscillator (VCO), and thereby improving phase noise also.

The present invention is also directed to improving flicker noise, that is, 1/f noise of an LC VCO to reduce a power value at a specific offset frequency and further improve phase noise.

One aspect of the present invention provides an LC VCO including: an LC resonant circuit including at least one inductor whose both ends are connected to an output node, and two variable capacitors connected in series with each other and in parallel with the inductor; and a first amplifier circuit including first and second negative resistance boosting transistors and first and second switching transistors. Here, drains of the first and second negative resistance boosting transistors are connected to the output node, gates and the drains of the first and second negative resistance boosting transistors are connected with each other, drains of the first and second switching transistors are connected with sources of the first and second negative resistance boosting transistors respectively, and gates of the first and second switching transistors are respectively connected with gates of the first and second negative resistance boosting transistors through capacitors and also connected with a predetermined bias voltage terminal through resistors.

A control voltage for changing capacitance values of the two variable capacitors to adjust a frequency of a signal output from the output node may be applied between the two variable capacitors.

The LC resonant circuit may further include at least one capacitor connected in parallel with the at least one inductor.

The inductor may be connected to a power supply terminal, sources of the first and second switching transistors may be connected to the ground, and the first and second negative resistance boosting transistors and the first and second switching transistors may be n-type transistors.

The LC VCO may further include a second amplifier circuit including two p-type transistors whose gates and drains are connected with each other and to the both ends of the at least one inductor and sources are connected to a power supply terminal. Here, sources of the first and second switching transistors may be connected to the ground, and the first and second negative resistance boosting transistors and the first and second switching transistors may be n-type transistors.

The inductor may be connected to the ground, sources of the first and second switching transistors may be connected to a power supply terminal, and the first and second negative resistance boosting transistors and the first and second switching transistors may be p-type transistors.

The LC VCO may further include a second amplifier circuit including two n-type transistors whose gates and drains are connected with each other and to the both ends of the at least one inductor and sources are connected to the ground. Here, sources of the first and second switching transistors may be connected to a power supply terminal, and the first and second negative resistance boosting transistors and the first and second switching transistors may be p-type transistors.

The LC VCO may further include a bias voltage supply circuit including a transistor for bias voltage supply. Here, a gate of the transistor for bias voltage supply may be connected with a drain and also with a source through a capacitor.

The bias voltage supply circuit may further include a current source for supplying current to the drain of the transistor for bias voltage supply.

### BRIEF DESCRIPTION OF THE DRAWINGS

The above and other objects, features and advantages of the present invention will become more apparent to those of ordinary skill in the art by describing in detail exemplary embodiments thereof with reference to the attached drawings, in which:

FIG. 1 is a circuit diagram of a conventional LC voltage-controlled oscillator (VCO);

FIG. 2 is a circuit diagram of an LC VCO according to a first exemplary embodiment of the present invention;

FIG. 3 is a graph for comparing the real number of a combined impedance seen from an output node of the LC VCO of FIG. 2 with the real number of a combined impedance seen from an output node of the LC VCO of FIG. 1;

FIG. 4A is a graph showing an output waveform of the LC VCO of FIG. 1 in an oscillation state;

FIG. 4B is a graph showing an output waveform of the LC VCO of FIG. 2 in the oscillation state;

FIG. 5A includes graphs showing phase noise of the LC VCOs of FIGS. 1 and 2 at an offset frequency of 1 MHz;

FIG. 5B includes graphs showing phase noise of the LC VCOs of FIGS. 1 and 2 at an offset frequency of 100 kHz;

FIG. 6 is a circuit diagram of an LC VCO according to a second exemplary embodiment of the present invention;

FIG. 7 is a circuit diagram of an LC VCO according to a third exemplary embodiment of the present invention; and

FIG. 8 is a circuit diagram of an LC VCO according to a fourth exemplary embodiment of the present invention.

### DETAILED DESCRIPTION OF EXEMPLARY EMBODIMENTS

Hereinafter, exemplary embodiments of the present invention will be described in detail. However, the present invention is not limited to the embodiments disclosed below but can be implemented in various forms. The following embodiments are described in order to enable those of ordinary skill in the art to embody and practice the present invention. To clearly describe the present invention, parts not relating to the description are omitted from the drawings. Like numerals refer to like elements throughout the description of the drawings.

Throughout this specification, when an element is referred to as being “connected” or “coupled” to another element, it can be directly connected or coupled to the other element or electrically connected or coupled to the other element with yet another element interposed between them.

Throughout this specification, when an element is referred to as “comprises,” “includes,” or “has” a component, it does not preclude another component but may further include the other component unless the context clearly indicates otherwise. Also, as used herein, the terms “ . . . unit,” “ . . . device,” “ . . . module,” etc., denote a unit of processing at least one function or operation, and may be implemented as hardware, software, or a combination of hardware and software.

### First Exemplary Embodiment

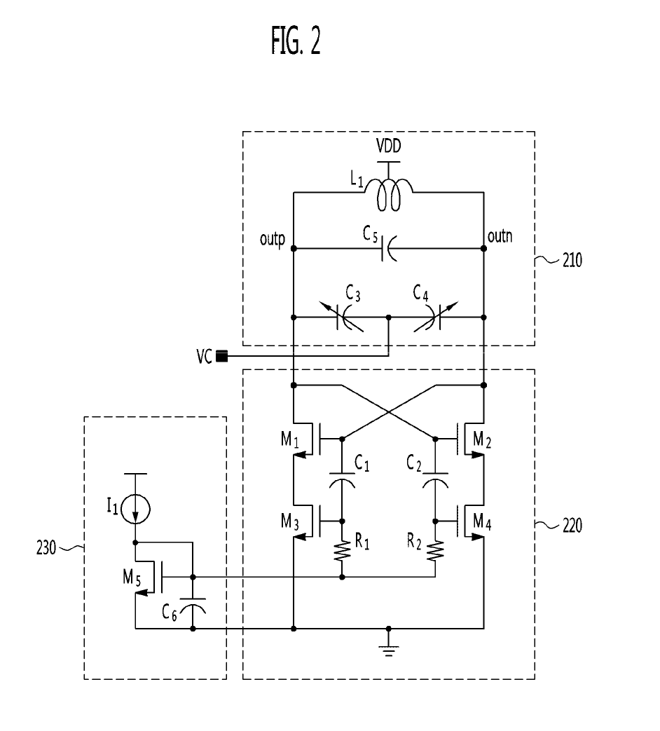

FIG. 2 is a circuit diagram of an LC voltage-controlled oscillator (VCO) according to a first exemplary embodiment of the present invention.

As shown in FIG. 2, an LC VCO according to the first exemplary embodiment of the present invention may include an LC resonant circuit 210, an amplifier circuit 220, and a bias voltage supply circuit 230.

First, the LC resonant circuit 210 may include an inductor L₁ connected to a power supply terminal VDD, a capacitor C₅ connected in parallel with the inductor L₁, and variable capacitors C₃ and C₄ connected in parallel with the inductor L₁ and the capacitor C₅. Both ends of the inductor L₁, the capacitor C₅, and a combination of the variable capacitors C₃ and C₄ connected in series are connected to a first node outp and a second node outn. Although one or two inductors may be included in the LC resonant circuit 210, FIG. 2 shows a case in which one inductor L₁ is included.

The amplifier circuit 220 may include one pair of negative resistance boosting transistors M₁ and M₂ and one pair of switching transistors M₃ and M₄. The gate nodes of the switching transistors M₃ and M₄ are connected to a bias voltage through resistors R₁ and R₂ respectively, and also to the gate nodes of the negative resistance boosting transistors M₁ and M₂ through capacitors C₁ and C₂ respectively. The source nodes of the switching transistors M₃ and M₄ are connected to the ground, and the drain nodes are connected to the source nodes of the negative resistance boosting transistors M₁ and M₂ respectively. While the gate node of the negative resistance boosting transistor M₁ is connected with the drain node of the negative resistance boosting transistor M₂, the gate node of the negative resistance boosting transistor M₂ is connected with the drain node of the negative resistance boosting transistor M₁.

Meanwhile, the bias voltage supply circuit 230 may include a current source I₁ and a transistor M₅ whose drain node and gate node are formed as a common node and connected with the gate nodes of the switching transistors M₃ and M₄ respectively through the resistors R₁ and R₂, and whose gate node is connected with the source node through a capacitor C₆. In the bias voltage supply circuit 230, the gate of the transistor M₅ has a uniform direct current (DC) voltage value due to the current source I₁. Although the bias voltage supply circuit 230 includes the current source I₁ and the transistor M₅ in FIG. 2, the constitution is not limited to this. A bias voltage supply circuit for applying a uniform DC voltage to the gates of the switching transistors M₃ and M₄ may be modified into various forms according to the necessity of those of ordinary skill in the art.

The operation principle of the LC VCO shown in FIG. 2 will be described below.

The oscillation frequency of the output signal of the LC VCO according to the first exemplary embodiment of the present invention can be expressed by Equation 1 below. Here, C₃₄ is a series-combined capacitance value of the variable capacitors C₃ and C₄.

$${f}_{osc} = \frac{1}{2 π \sqrt{{L}_{1} \cdot ( {C}_{34} + {C}_{5} )}} \qquad [ Equation 1 ]$$

In other words, the oscillation frequency is changed by the inductance value of the inductor L₁, the capacitance value of the capacitor C₅, or the combined capacitance value, C₃₄ of the variable capacitors C₃ and C₄. Since the inductance value of the inductor L₁ cannot be successively changed, a control voltage vc is supplied between the variable capacitors C₃ and C₄ to change the combined capacitance value C₃₄ of the variable capacitors C₃ and C₄, so that the oscillation frequency of the output signal can be adjusted.

Meanwhile, the oscillation signal amplitude of the LC VCO in an oscillation state is determined by a combined impedance as shown in Equation 2 below.

$${Z}_{total} = \frac{1}{{G}_{m} + {G}_{LC}} \qquad [ Equation 2 ]$$

Here, Gₘ is the negative conductance (Gₘ<0) of the amplifier circuit 220, and G_{LC} is the conductance (G_{LC}>0) of the LC resonant circuit 210. In other words, the amplitude of the oscillation signal is determined as the reciprocal of a combined conductance obtained by combining the negative conductance of the amplifier circuit 220 and the conductance of the LC resonant circuit 210. For oscillation, the combined impedance needs to have a negative value. The greater the absolute value of the combined impedance, the larger the amplitude of the oscillation signal.

When the amplifier circuit 220 is seen from the nodes outp and outn, the reciprocal of a negative resistance, that is, a negative conductance, can be expressed in a high frequency domain by Equation 3 below.

$${G}_{m} \approx - {g}_{m 2} - \frac{{g}_{m 1}}{1 + {g}_{m 1} {r}_{o}} \qquad [ Equation 3 ]$$

Here, gₘ₂ is the transconductance of the switching transistors M₃ and M₄, gₘ₁ is the transconductance of the negative resistance boosting transistors M₁ and M₂, and rₒ is the output impedance value of the switching transistors M₃ and M₄. The amplitude of the oscillation signal varies according to the reciprocal of the combined conductance obtained by combining the negative conductance of the amplifier circuit 220 expressed as mentioned above and the conductance of the LC resonant circuit 210. The term

$$- \frac{{g}_{m 1}}{1 + {g}_{m 1} {r}_{0}}$$

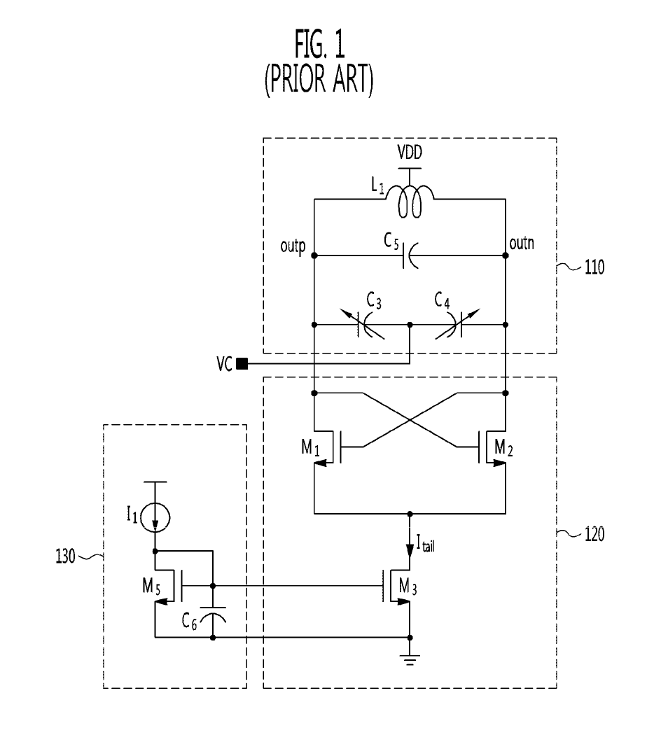

of Equation 3 can correspond to a lower negative value due to the constitution of the amplifier circuit 220 according to the first exemplary embodiment of the present invention in which the transistor M₃ serving as a current source in the amplifier circuit 120 of FIG. 1 is implemented by the two switching transistors M₃ and M₄, and the resistors R₁ and R₂ and the capacitors C₁ and C₂ are added so that the switching transistors M₃ and M₄ can operate as amplifiers. Thus, the LC VCO according to the first exemplary embodiment of the present invention can obtain the same negative conductance value using relatively small current, and implement a desired oscillation state.

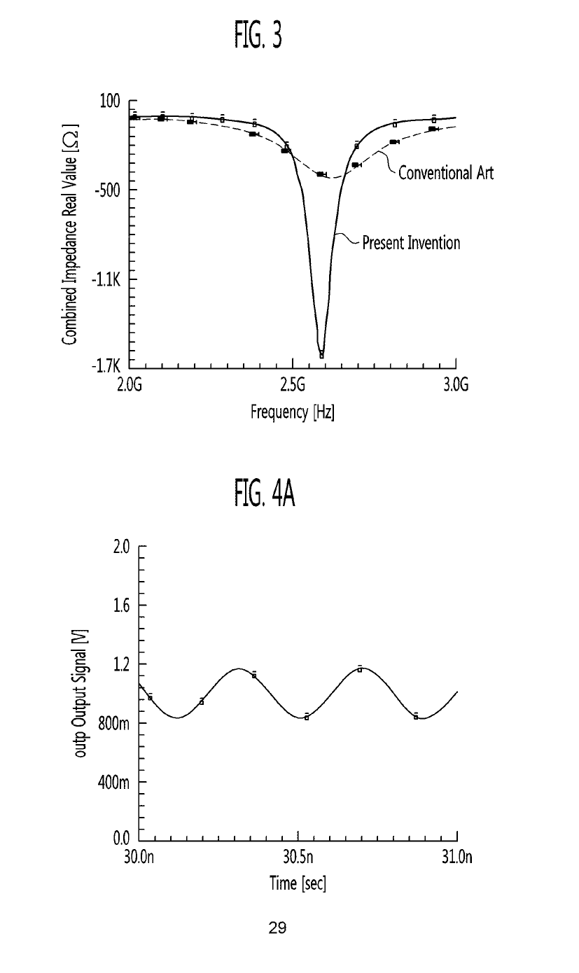

FIG. 3 is a graph showing the real number of a combined impedance seen from the differential output nodes outp and outn of the LC VCO of FIG. 2 together with the real number of a combined impedance seen from the differential output nodes outp and outn of the conventional LC VCO of FIG. 1.

Referring to FIG. 3, while a combined impedance real number of the conventional LC VCO in the oscillation state is about −420Ω, a combined impedance real number of the LC VCO of FIG. 2 is about −1.6 kΩ, which is four times or more that of the conventional LC VCO. In other words, the LC VCO according to the first exemplary embodiment of the present invention can be driven by relatively small current.

Meanwhile, the index of phase noise L(Δf) of an oscillator can be expressed by Equation 4 below. Here, P_{sig}(fₒ) is the power value of an oscillation frequency, and Pₙₒᵢₛₑ(Δf) is a power value at the position spaced apart from the oscillation frequency by a specific offset frequency.

$$L ( Δ f ) = 20 log ( \frac{{P}_{sig} ( {f}_{o} )}{{P}_{noise} ( Δ f )} ) \qquad [ Equation 4 ]$$

In other words, the phase noise index is defined as a difference between P_{sig}(fₒ) and Pₙₒᵢₛₑ(Δf), and phase noise performance can be improved by increasing the signal level of the oscillation frequency or reducing the power value at the specific offset frequency. In the LC VCO according to the first exemplary embodiment of the present invention, the signal level of the oscillation frequency is very high, so that phase noise can be improved.

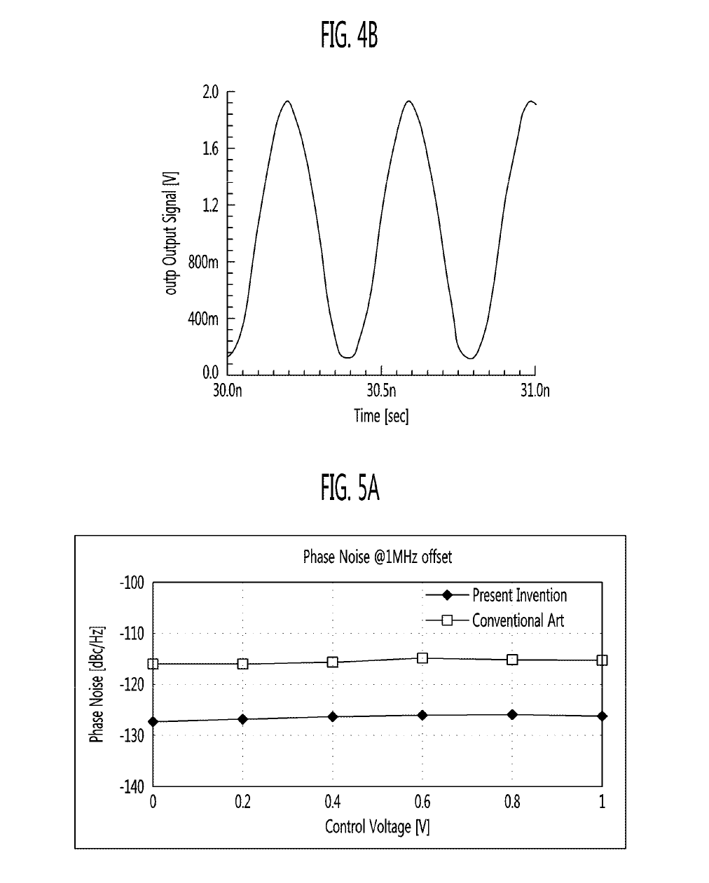

FIG. 4 includes graphs showing output waveforms of LC VCOs in the oscillation state. FIG. 4A is a graph showing the output waveform of the conventional LC VCO shown in FIG. 1 in the oscillation state, and FIG. 4B is a graph showing the output waveform of the LC VCO of FIG. 2 in the oscillation state.

Referring to FIGS. 4A and 4B, while an output signal amplitude at the output node outp of the conventional LC VCO is about 100 mV centering around a power supply voltage of 1 V, the LC VCO according to the first exemplary embodiment of the present invention oscillates with an amplitude of about 900 mV centering around a power supply voltage of 1 V. In other words, the LC VCO according to the first exemplary embodiment of the present invention can obtain an output signal having a very large amplitude in comparison with the conventional LC VCO, and thus the phase noise of the LC VCO can be improved.

Also, by the LC VCO according to the first exemplary embodiment of the present invention, 1/f noise of a current source that is a factor increasing a power value Pₙₒᵢₛₑ(Δf) at a specific offset frequency is improved. In other words, while large 1/f noise is generated from the transistor M₃ functioning as a current source in the conventional LC VCO shown in FIG. 1, 1/f noise can be improved in the LC VCO of FIG. 2 because the transistor M₃ of FIG. 1 is implemented by one pair of the switching transistors M₃ and M₄ in the LC VCO of FIG. 2 and operates as an amplifier as well as a current source. Thus, the power value Pₙₒᵢₛₑ(Δf) decreases, and overall phase noise can be further improved.

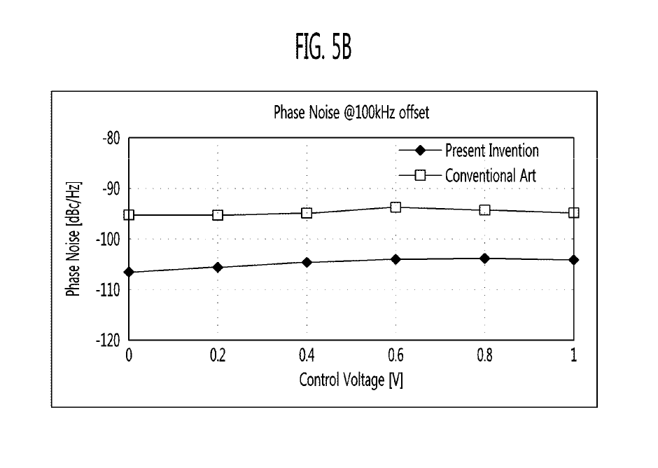

FIG. 5 includes graphs showing phase noise of a conventional LC VCO and the LC VCO according to the first exemplary embodiment of the present invention. FIG. 5A is a graph showing phase noise at an offset frequency of 1 MHz, and FIG. 5B is a graph showing phase noise at an offset frequency of 100 kHz. Devices included in each LC VCO are implemented by complementary metal oxide semiconductor (CMOS) models of Taiwan Semiconductor Manufacturing Company, Limited (TSMC).

Referring to FIGS. 5A and 5B, the LC VCO according to the first exemplary embodiment of the present invention shows lower phase noise than the conventional LC VCO by about 8 dB or more at both of the offset frequencies of 1 MHz and 100 kHz. In other words, the LC VCO according to the first exemplary embodiment of the present invention has remarkably improved phase noise performance.

### Second Exemplary Embodiment

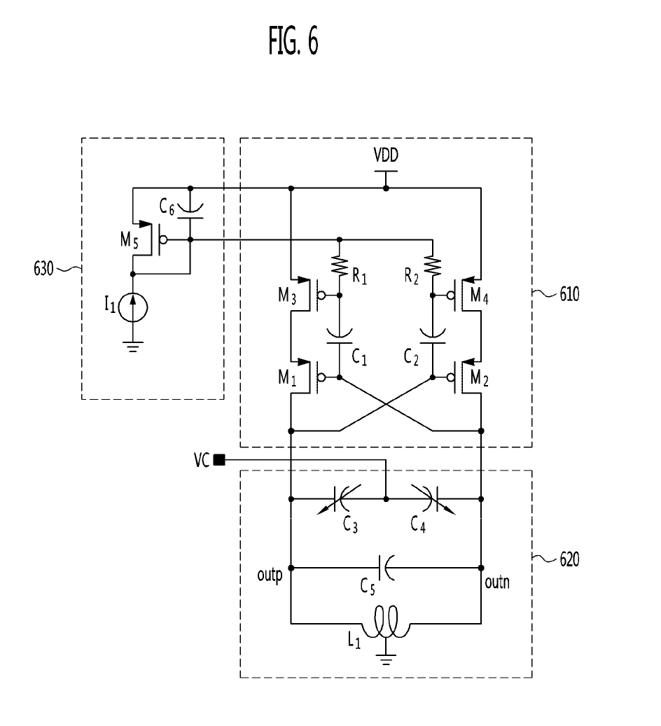

FIG. 6 is a circuit diagram of an LC VCO according to a second exemplary embodiment of the present invention.

Referring to FIG. 6, in an LC VCO according to the second exemplary embodiment of the present invention, all n-type transistors included in the LC VCO according to the first exemplary embodiment of the present invention shown in FIG. 2 are replaced by p-type transistors, and the positions of the power supply terminal VDD and the ground terminal are changed with each other.

The constitution of the LC VCO according to the second exemplary embodiment of the present invention will be described in detail below. The LC VCO according to the second exemplary embodiment of the present invention also includes an amplifier circuit 610, an LC resonant circuit 620, and a bias voltage supply circuit 630.

The LC resonant circuit 610 has the same constitution as the LC resonant circuit 210 of the LC VCO shown in FIG. 2 except that an inductor L₁ is connected to the ground instead of the power supply terminal VDD.

Also, the amplifier circuit 620 has the same constitution as the amplifier circuit 220 of the LC VCO shown in FIG. 2 except that all transistors M₁, M₂, M₃ and M₄ are p-type transistors and the source terminals of one pair of switching transistors M₃ and M₄ are connected to the power supply terminal VDD.

Meanwhile, the bias voltage supply circuit 630 has the same constitution as the bias voltage supply circuit 230 of the LC VCO shown in FIG. 2 except that a transistor M₅ included in the bias voltage supply circuit 630 is a p-type transistor and the source node of the transistor M₅ is connected to the power supply terminal VDD.

### Third Exemplary Embodiment

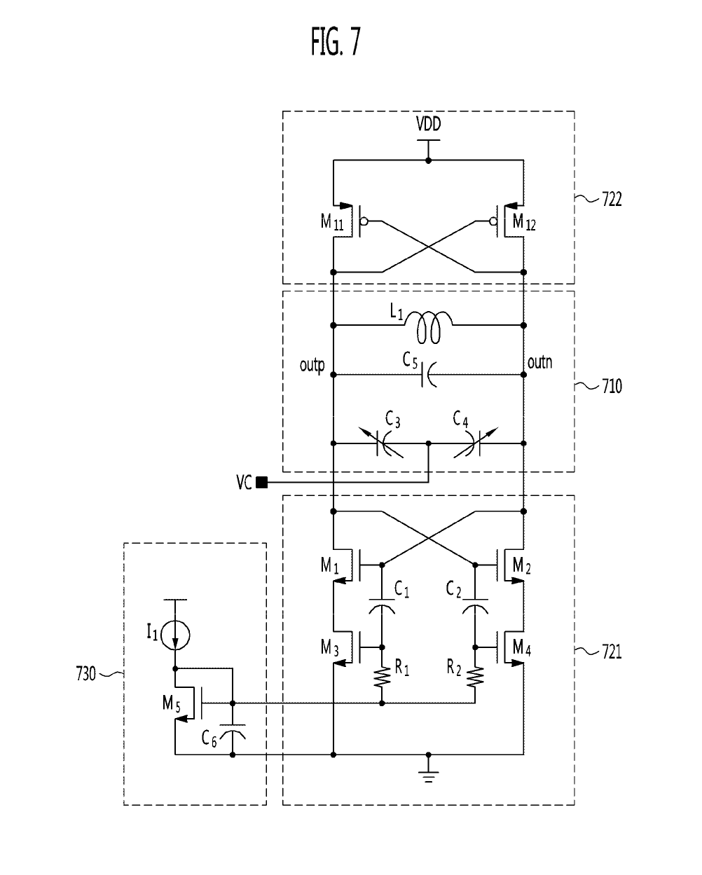

FIG. 7 is a circuit diagram of an LC VCO according to a third exemplary embodiment of the present invention.

An LC VCO shown in FIG. 7 is the LC VCO of FIG. 2 implemented using a compensation circuit.

Referring to FIG. 7, in the LC VCO according to the third exemplary embodiment of the present invention, an amplifier circuit 721 implemented by n-type transistors and an amplifier circuit 722 implemented by p-type transistors are simultaneously present. The amplifier circuit 721 implemented by n-type transistors has the same structure as the amplifier circuit 220 of FIG. 2, and the amplifier circuit 722 implemented by p-type transistors is connected to a power supply terminal VDD. To be specific, the gate nodes and drain nodes of p-type transistors M₁₁ and M₁₂ included in the amplifier circuit 722 are connected with each other and to the both ends of an inductor L₁ included in an LC resonant circuit 710, and the source nodes are connected to the power supply terminal VDD. The LC resonant circuit 710 and a bias voltage supply circuit 730 have the same constitutions as those 210 and 230 of the LC VCO of FIG. 2, and the description will not be reiterated.

Since the amplifier circuit 721 implemented by n-type transistors and the amplifier circuit 722 implemented by p-type transistors are simultaneously present in the LC VCO according to the third exemplary embodiment of the present invention, the negative conductance value is the sum of negative conductance values that the two amplifier circuits 721 and 722 have and thus can increase. Thus, the LC VCO according to the third exemplary embodiment of the present invention can be placed in the oscillation state to have a desired amplitude using relatively small current.

### Fourth Exemplary Embodiment

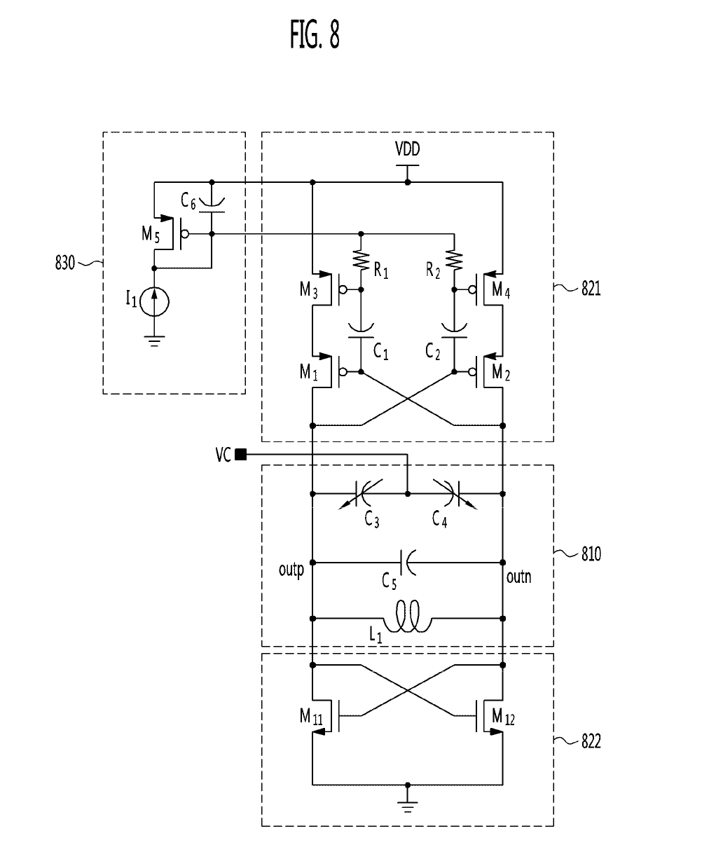

FIG. 8 is a circuit diagram of an LC VCO according to a fourth exemplary embodiment of the present invention.

An LC VCO shown in FIG. 8 is the LC VCO of FIG. 6 implemented using a compensation circuit.

Referring to FIG. 8, in the LC VCO according to the fourth exemplary embodiment of the present invention, an amplifier circuit 821 implemented by p-type transistors and an amplifier circuit 822 implemented by n-type transistors are simultaneously present. The amplifier circuit 821 implemented by p-type transistors has the same structure as the amplifier circuit 620 of FIG. 6, and the amplifier circuit 822 implemented by n-type transistors is connected to the ground. To be specific, the gate nodes and drain nodes of n-type transistors M₁₁ and M₁₂ included in the amplifier circuit 822 are connected with each other and to the both ends of an inductor L₁ included in an LC resonant circuit 810, and the source nodes are connected to the ground. The LC resonant circuit 810 and a bias voltage supply circuit 830 have the same constitutions as those 620 and 630 of the LC VCO of FIG. 6, and the description will not be reiterated.

As described above, since an LC VCO according to an exemplary embodiment of the present invention includes an amplifier circuit having a high impedance value, it is possible to output an oscillation signal having an improved amplitude and to exhibit improved phase noise.

Also, flicker noise, that is, 1/f noise, of an LC VCO according to an exemplary embodiment of the present invention is improved, so that a power value at a specific offset frequency can be reduced and phase noise also can be improved.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. An LC voltage-controlled oscillator (VCO), comprising:
an LC resonant circuit including at least one inductor whose both ends are connected to an output node, and two variable capacitors connected in series with each other and in parallel with the inductor; and
a first amplifier circuit including first and second negative resistance boosting transistors and first and second switching transistors,
wherein drains of the first and second negative resistance boosting transistors are connected to the output node,
gates and the drains of the first and second negative resistance boosting transistors are connected with each other,
drains of the first and second switching transistors are connected with sources of the first and second negative resistance boosting transistors respectively, and
gates of the first and second switching transistors are respectively connected with gates of the first and second negative resistance boosting transistors through capacitors and also connected with a predetermined bias voltage terminal through resistors.

2. The LC VCO of claim 1, wherein a control voltage for changing capacitance values of the two variable capacitors to adjust a frequency of a signal output from the output node is applied between the two variable capacitors.

3. The LC VCO of claim 1, wherein the LC resonant circuit further includes at least one capacitor connected in parallel with the at least one inductor.

4. The LC VCO of claim 1, wherein the inductor is connected to a power supply terminal,
sources of the first and second switching transistors are connected to the ground, and
the first and second negative resistance boosting transistors and the first and second switching transistors are n-type transistors.

5. The LC VCO of claim 1, further comprising a second amplifier circuit including two p-type transistors whose gates and drains are connected with each other and to the both ends of the at least one inductor and sources are connected to a power supply terminal,
wherein sources of the first and second switching transistors are connected to the ground, and
the first and second negative resistance boosting transistors and the first and second switching transistors are n-type transistors.

6. The LC VCO of claim 1, wherein the inductor is connected to the ground,
sources of the first and second switching transistors are connected to a power supply terminal, and
the first and second negative resistance boosting transistors and the first and second switching transistors are p-type transistors.

7. The LC VCO of claim 1, further comprising a second amplifier circuit including two n-type transistors whose gates and drains are connected with each other and to the both ends of the at least one inductor and sources are connected to the ground,
wherein sources of the first and second switching transistors are connected to a power supply terminal, and
the first and second negative resistance boosting transistors and the first and second switching transistors are p-type transistors.

8. The LC VCO of claim 1, further comprising a bias voltage supply circuit including a transistor for bias voltage supply,
wherein a gate of the transistor for bias voltage supply is connected with a drain and also with a source through a capacitor.

9. The LC VCO of claim 8, wherein the bias voltage supply circuit further includes a current source for supplying current to the drain of the transistor for bias voltage supply.
